(19) United States
(12) Patent Application Publication
(10) Pub. No.: US 2024/0258262 A1
(43) Pub. Date: Aug. 1, 2024

(54) MULTI-BARRIER SYSTEM FOR LOW-VOID THERMAL TRANSFER

(71) Applicant: THE INDIUM CORPORATION OF AMERICA, Clinton, NY (US)

(72) Inventors: Milos Lazic, New Hartford, NY (US); Richard McDonough, Oneida, NY (US)

(21) Appl. No.: 18/426,144

(22) Filed: Jan. 29, 2024

Related U.S. Application Data
(60) Provisional application No. 63/442,653, filed on Feb. 1, 2023.

(51) Int. Cl. H01L 23/00; H01L 23/367

(52) U.S. Cl. CPC H01L 24/26; H01L 23/367; H01L 24/27; H01L 24/29; H01L 24/32; H01L 24/83; H01L 2224/26175; H01L 2224/27013; H01L 2224/2732; H01L 2224/29105; H01L 2224/3207; H01L 2224/32221; H01L 2224/83201; H01L 2924/0103; H01L 2924/01049; H01L 2924/0105

(57) ABSTRACT

Described are a double barrier system and method used to contain a thermal interface material to avoid unwanted interactions of the thermal interface material with other metals or components within a semiconductor device. In one implementation, a semiconductor assembly includes: a substrate; a heat generating device including a first surface attached to the substrate; a first barrier surrounding and in touching relation with the heat generating device; a second barrier surrounding the first barrier such that there is an area between the first barrier and the second barrier; a heat transferring device; and a thermal interface material between and in touching relation with the heat transferring device and a second surface of the heat generating device opposite the first surface.

### CROSS-REFERENCE TO RELATED APPLICATIONS

The present application claims the benefit of U.S. Provisional Patent Application No. 63/442,653 filed on Feb. 1, 2023 and titled “MULTI-BARRIER SYSTEM FOR LOW-VOID THERMAL TRANSFER,” which is incorporated herein by reference in its entirety.

### DESCRIPTION OF THE RELATED ART

With the rising popularity of artificial intelligence semiconductor processors, high performance computing chips, and graphic-heavy gaming systems, efficiently removing heat from these devices remains a primary concern to achieve optimal performance of the system. Various thermal interface materials (TIMs) are currently employed to facilitate heat removal from these devices. These materials include, greases, phase change materials, metals, foils, conductive pastes and most recently, liquid metals.

Some liquid metals have both high thermal conductivity and low thermal surface resistivity. This combination makes these materials ideal for TIMs. Often these liquid metals are gallium-based. Gallium metal is liquid at 29.8° C. To further reduce the melting point additional metals can be added. For example a ˜3:1 ratio of gallium to indium remains liquid at 15.7° C. The solidus point can be further reduced by the addition of tin. A ratio of 68.5Ga 21.5In 10Sn melts at 11° C.

### SUMMARY

Some implementations of the disclosure are directed to a double barrier system and method used to contain TIMs (e.g., liquid metal TIMs) to avoid unwanted interactions of the TIM with other metals or components within a semiconductor device.

In one embodiment, an assembly comprises: a substrate; a heat generating device including a first surface attached to the substrate; a first barrier surrounding and in touching relation with the heat generating device; a second barrier surrounding the first barrier such that there is an area between the first barrier and the second barrier; a heat transferring device; and a thermal interface material between and in touching relation with the heat transferring device and a second surface of the heat generating device opposite the first surface.

In some implementations, the heat transferring device is in touching relation with the first barrier and the second barrier.

In some implementations, the first barrier and the second barrier are in touching relation with the substrate.

In some implementations, a height of the first barrier is substantially equal to a height of the second barrier; and the height of the first barrier is substantially equal to a distance between a surface of the heat generating device contacting the substrate and a surface of the heat transferring device contacting the thermal interface material.

In some implementations, the thermal interface material fills at least part of the area between the first barrier and the second barrier.

In some implementations, the thermal interface material is hermetically sealed by the second barrier.

In some implementations, the area between the first barrier and the second barrier continuously surrounds a perimeter of the first barrier such that the first barrier and second barrier are not in touching relation anywhere.

In some implementations, the first barrier and the second barrier comprise a dielectric material.

In some implementations, the dielectric material comprises silicone or a urethane acrylate.

In some implementations, the first barrier comprises a UV curable, acrylated urethane.

In some implementations, the second barrier comprises a thermally curable silicone.

In some implementations, the thermal interface material comprises gallium, indium, tin, copper, zinc, gold, silver, antimony, or bismuth.

In some implementations, the thermal interface material comprises gallium and indium in a ratio ranging from 3:1 to 4:1 of gallium to indium.

In some implementations, the thermal interface material comprises: 61 wt % to 68.5 wt % gallium; 20 wt % to 25 wt % indium; 8 wt % to 16 wt % tin; and optionally, greater than 0 wt % to 2 wt % zinc.

In some implementations, the heat generating device comprises a semiconductor die; and the heat transferring device comprises a heat sink or heat spreader.

In one embodiment, a method comprises: attaching a first surface of a heat generating device to a substrate; placing, on the substrate, a first barrier that surrounds and is in touching relation with the heat generating device; placing, on the substrate, a second barrier that surrounds the first barrier such that there is an area between the first barrier and the second barrier; after placing the first barrier and the second barrier, applying a thermal interface material on a second surface of the heat generating device opposite the first surface; and compressing a heat transferring device over the heat generating device until a surface of the heat transferring device is in touching relation with the thermal interface material applied on the second surface of the heat generating device.

In some implementations, the method further comprises: prior to compressing the heat transferring device over the heat generating device, curing, using heat or ultraviolet light, the first barrier to a solid form, wherein during compression of the heat transferring device over heat generating device, the first barrier in the solid form controls a standoff height between the heat generating device and the heat transferring device.

In some implementations, compressing the heat transferring device over the heat generating device comprises compressing the heat transferring device until the surface of the transferring device is in touching relation with the first barrier, the second barrier, and the thermal interface material.

In some implementations, compressing the heat transferring device over the heat generating device comprises compressing the heat transferring device such that a portion of the thermal interface material flows over the first barrier into the area between the first barrier and the second barrier.

In some implementations, compressing the heat transferring device over the heat generating device comprises compressing the second barrier to a compressed state; and the method further comprises: after compressing the heat transferring device over the heat generating device, curing the second barrier in the compressed state.

In some implementations, prior to compressing the heat transferring device over the heat generating device: a height of the first barrier is less than a height of the second barrier, and a height of the first barrier is less than a combined height of the heat generating device and the thermal interface material on the second surface of the heat generating device. In addition, prior to compressing the heat transferring device over the heat generating device, the combined height can be less than a height of the second barrier.

In some implementations, after compressing the heat transferring device over the heat generating device: the height of the first barrier is substantially the same as the height of the second barrier, and the height of the first barrier is substantially the same as the combined height of the heat generating device and the thermal interface material on the second surface of the heat generating device.

In some implementations, the heat generating device comprises a semiconductor die; and the heat transferring device comprises a heat sink or heat spreader.

Other features and aspects of the disclosed technology will become apparent from the following detailed description, taken in conjunction with the accompanying drawings, which illustrate, by way of example, the features in accordance with implementations of the disclosed technology. The summary is not intended to limit the scope of any inventions described herein, which are defined by the claims and equivalents.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

### BRIEF DESCRIPTION OF THE DRAWINGS

The present disclosure, in accordance with one or more implementations, is described in detail with reference to the following figures. The figures are provided for purposes of illustration only and merely depict example implementations. Furthermore, it should be noted that for clarity and ease of illustration, the elements in the figures have not necessarily been drawn to scale.

Some of the figures included herein illustrate various implementations of the disclosed technology from different viewing angles. Although the accompanying descriptive text may refer to such views as “top,” “bottom” or “side” views, such references are merely descriptive and do not imply or require that the disclosed technology be implemented or used in a particular spatial orientation unless explicitly stated otherwise.

FIG. 1A shows a top plan view of a semiconductor assembly with a double barrier system, prior to applying a TIM, in accordance with some implementations of the disclosure.

FIG. 1B shows a top plan view of the semiconductor assembly of FIG. 1A after directly applying the TIM to a heat generating device.

FIG. 1C shows a top plan view of the semiconductor assembly of FIG. 1B, after compression with a heat transferring device, showing a liquid metal contained by the double barrier system.

FIG. 2A shows a cross-sectional view of a semiconductor assembly with a double barrier system, after directly applying a TIM to a heat generating device, in accordance with some implementations of the disclosure.

FIG. 2B shows a cross-sectional view of the semiconductor assembly of FIG. 2A with the double barrier system, during compression with a heat transferring device, showing a liquid metal contained by the double barrier system.

The figures are not exhaustive and do not limit the present disclosure to the precise form disclosed.

### DETAILED DESCRIPTION OF THE EMBODIMENTS

While indium and tin readily dissolve in liquid gallium to create alloys with reduced solidus points, gallium's reaction with other metals may be undesirable. For example a printed circuit board (PCB) may contain copper pads and copper or aluminum containing components populated on the PCB. Gallium-containing liquid alloys will readily dissolve aluminum and copper which could become problematic if the gallium-based TIM flows from its TIM position onto the PCB or onto other components within the device.

One possible strategy to contain the liquid metal TIM within a semiconductor assembly is through the use of a barrier. Liquid metal is prone to leaking from the chip top surface during repeated power cycling of the device. A barrier creates a containment for liquid metal that may leak from the topside of the semiconductor chip. This protects sensitive components and metals that may be soluble in gallium-based liquid metals. Additional protection may be employed by depositing a polymer-based underfill material between the semiconductor chip and the barrier to overcoat any sensitive components prone to interact with gallium metal. While this combination of a barrier perimeter and underfill coating may protect components from interacting with the liquid metal, it does not optimize the liquid metal contact with the chip. It is still possible for voids in the liquid metal to be present between the heat generating device and the heat transferring device, thereby lowering the overall efficiency.

A barrier may also be useful for solid TIMs such as indium foil. Once the indium foil is raised above its solidus point it will liquefy and may flow outside of its TIM position and onto the PCB. While indium metal is not likely to dissolve other metals on the PCB as would gallium-based TIMs, it could cause a short circuit between components on the PCB. As such, what is needed is a barrier system for TIMs dispensed in liquid form and/or for TIMs that reach a temperature above the solidus point during operation of the heat generating device.

To this end, implementations of the disclosure are directed to a double barrier system and method used to contain TIMs (e.g., liquid metal TIMs) to avoid unwanted interactions of the TIM (e.g., liquid metal) with other metals or components within a semiconductor device. The double barrier system and method described herein can be particularly suited for containing liquid metal TIMs in the TIM 0 or TIM 1 configuration, where a TIM 0 configuration refers to a TIM placed between the semiconductor die and the heat sink, and a TIM 1 configuration refers to A TIM placed between the semiconductor device and heat spreader.

By virtue of implementing the double barrier system, TIM (e.g., liquid metal) voids between a heat generating device and heat transferring device can be reduced or avoided. In addition, the double barrier system can create a hermetic seal to contain the TIM (e.g., liquid metal) between the barriers and prevent oxidation of the TIM. Additionally, the first barrier can control the standoff between the heat generating device and the heat transferring device. These and other potential advantages of implementing the technology described herein are further described below.

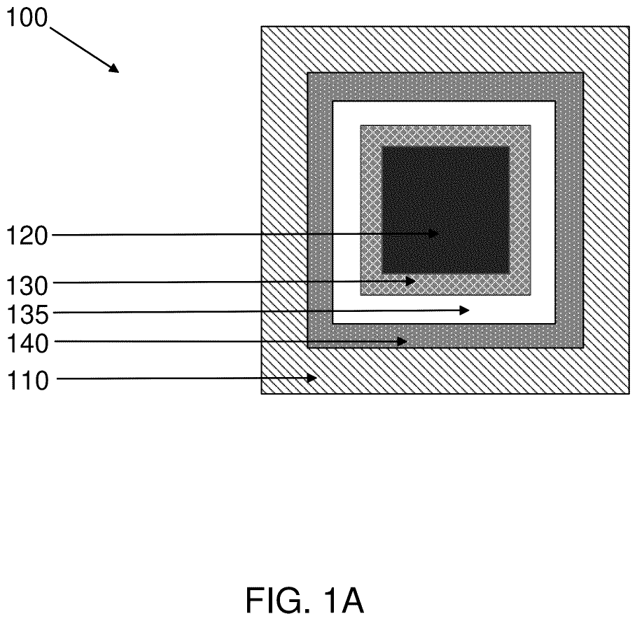

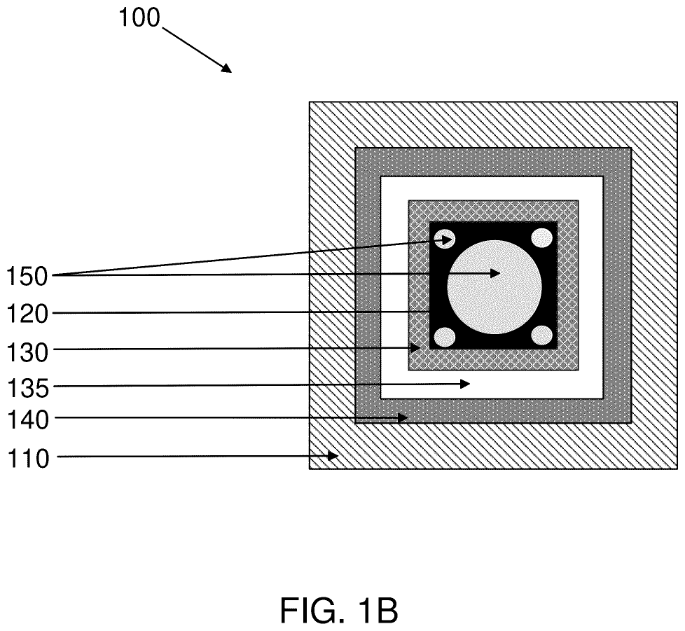

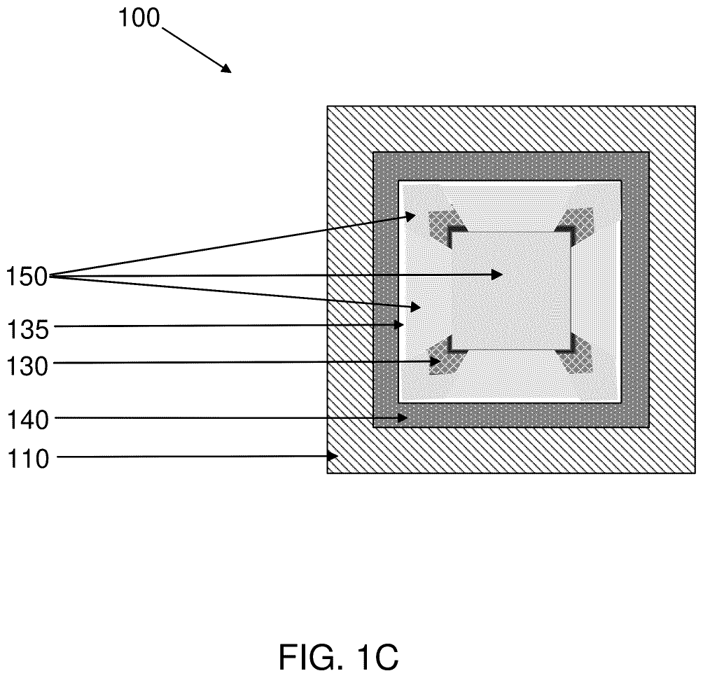

FIGS. 1A-1C show top plan views of a semiconductor assembly 100 including a double barrier system, at different stages of assembly with a TIM, in accordance with some implementations of the disclosure. FIG. 1A shows the semiconductor assembly 100 with the double barrier system, prior to applying the TIM. FIG. 1B shows the semiconductor assembly 100 with the double barrier system, after directly applying the TIM to a heat generating device 120. FIG. 1C shows the semiconductor assembly 100 with the double barrier system, after compression with a heat transferring device (not shown), showing a liquid metal contained by the double barrier system. For ease of illustration of the double barrier system, the heat transferring device of the semiconductor assembly 100 is omitted from illustration.

As depicted, the heat generating device or chip/die 120 is mounted to a substrate 110 (e.g., PCB) using a conductive adhesive such as solder, a sintering paste, a metal-filled conductive epoxy, or other suitable adhesive. FIG. 1A shows the top side of the die 120 opposite the side secured to the substrate 110. The conductive adhesive (not shown) is located between one side of the die 120 and the substrate 110. The die 120 can be securely fashioned to substrate 110 by exposing die 120 to a thermal reflow.

Also depicted is a double barrier system including a first barrier 130, a second barrier 140, and an overflow area 135 between the first barrier 130 and the second barrier 140. The first barrier 130 can be dispensed around the die 120 onto substrate 110 such that the first barrier 130 is in touching relation with the die 120. For example, the first barrier 130 can touch the four sides of the die 120 perpendicular to the topside. The outer wall of the first barrier 130, opposite the side touching the die 120, can define the innermost wall of the overflow area 135. The overflow area 135 can extend from the outer wall of the first barrier 130 to the inner most wall of the second barrier 140. The substrate 110 can occupy the “floor” between the first barrier 130 and the second barrier 140 such that the height of the first barrier 130 and the height of the second barrier 140 extend above the substrate 110, creating a “trench” that defines the overflow area 135.

As depicted, the first barrier 130 can extend continuously around the perimeter of the die 120 such that the innermost perimeter of the first barrier 130 is in touching relation with the outer perimeter of the die 120 and such that the outermost wall of the first barrier 130 is in touching relation with the overflow area 135. In other implementations, not illustrated herein, there can be a slight gap between the die 120 perimeter and the first barrier 130 such that the die 120 and the first barrier 130 are not in touching relation.

The second barrier 140 can extend continuously around the first barrier 130 such that the first barrier 130 and second barrier 140 are not in touching relation. The innermost perimeter wall of the second barrier 140 can be in touching relation with the substrate 110 and serve as the outermost perimeter of the overflow area 135. The outermost perimeter wall of the second barrier 140 can be in touching relation with the substrate 110 and define the boundary with the remaining portion of the substrate extending outward from the second barrier away from the die.

In some implementations, components attached to the substrate that populate the area within the overflow area 135, can be protected with a dielectric material to prevent unwanted interaction with the TIM.

As depicted in FIG. 1B, during assembly, the TIM 150 can be applied directly to the die 120 to provide a thermal interface between die 120 and a heat transferring device (not shown). TIM 150 can take the form of a liquid metal or liquid metal foam deposited onto the die 120 by dispensing equipment, brush, screen printing or by any other method such that the liquid metal TIM 150 is transferred to the heat generating device 120. The TIM 150 can be comprised of gallium or bismuth-based alloys such that the metal or metal alloy TIM can be dispensed onto the die 120. In other implementations, the TIM can be a grease in paste form or a metal or metal alloy in solid form such that upon operation of the heat generating device/die 120, a decrease in viscosity occurs.

An excess of TIM 150 can be applied to the heat generating device 120 such that during the compression of the heat transferring device onto the heat generating device 120, the liquid metal is transferred over the top of the die 120. The excess of TIM 150 can be transferred to the outer perimeter of the die 120 such that the TIM material is in touching relation with the first barrier 130. In some implementations, the TIM 150 can flow over the first barrier 130 into the overflow area 135 such that the TIM 150 is contained between the first barrier 130 and the second barrier 140.

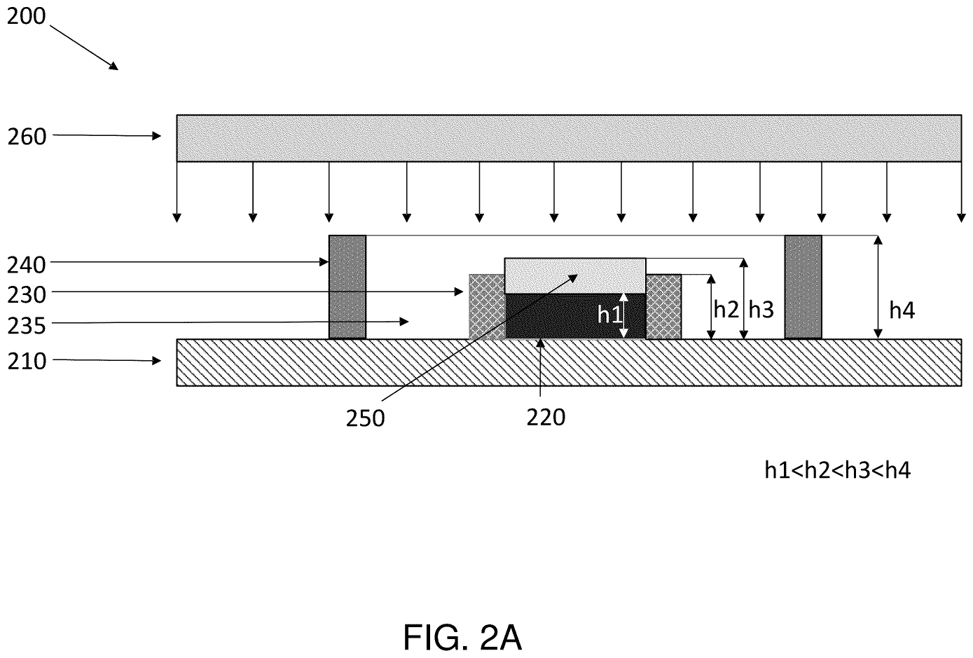

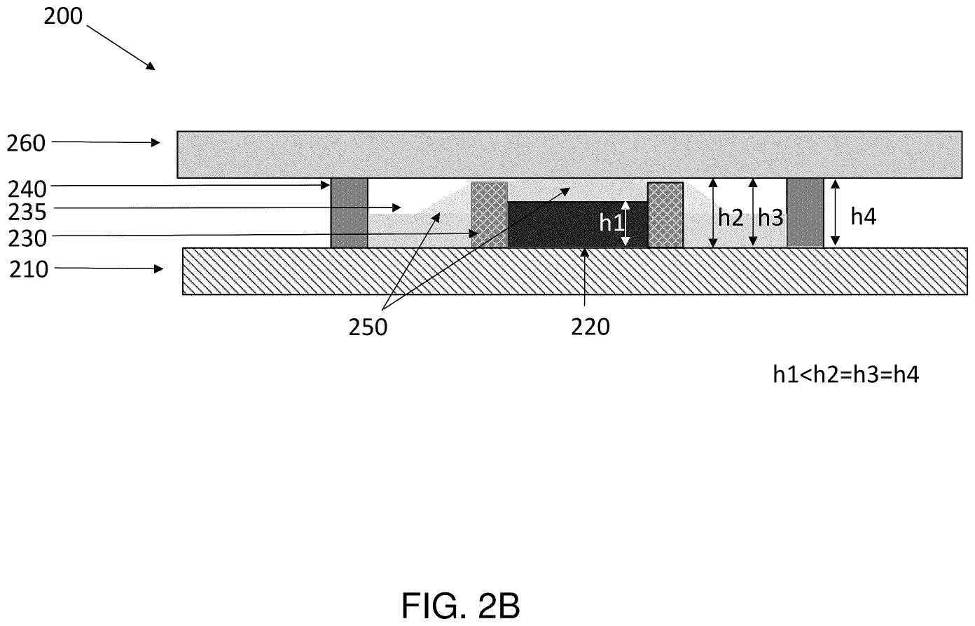

In some implementations, the TIM 150 can be patterned onto the surface of the heat generating device 120 to optimize contact of the TIM 150 between the heat generating device 120 and the heat transferring device. For example, the TIM 150 can be dispensed in spirals originating at the center of the die 120 and spiraling outward towards the four outermost edges of the top side of the die 120. In some implementations, and as shown in FIG. 2A, the TIM 150 can be dispensed onto the center of the top side of the die 120 with additional deposits of TIM 150 applied to the top side corners of the die 120.

The double barrier system of semiconductor assembly 100 can contain the TIM 150 and prevent any unwanted interaction of the TIM 150 with the rest of the assembly or components. For example, FIG. 1C shows the semiconductor assembly 100, post-compression (e.g., caused by placement of a heat transferring device on TIM 150), demonstrating that the TIM 150 has been contained by the double barrier system. The TIM 150 is shown as flowing over the first barrier 130 into the overflow area 135 such that it is in touching relation with the first barrier 130 and the second barrier 140. It can also be in touching relation with the substrate 110.

In implementations where the TIM 150 is deposited onto the top side of the die 120 in a pattern, such as a spiral, the pattern can be eliminated during compression and the TIM can be uniformly dispersed over the top side of the die 120.

During compression, the TIM 150 can flow towards the outer edges of the top side of the die 120 towards the first barrier. In some embodiments the TIM will flow over the first barrier 130 into the overflow area 135 and become contained by the outermost wall of the first barrier 130, the substrate 110 “floor” within the overflow area 135, and the innermost wall of the second barrier 140. The heat transferring device, when compressed onto the semiconductor assembly 100, fully contains any TIM 150, on all sides, within the overflow area 135 cavity.

During compression between the heat transferring device and heat generating device 120, the TIM 150 can flow towards the outer edges of the top side of the die 120 towards the first barrier 130. In some implementations, the TIM 150 will flow over the first barrier 130 into the overflow area 135 and become contained by the outermost wall of the first barrier 130, the substrate 110 “floor” within the overflow area 135, and the innermost wall of the second barrier 140. Any TIM 150 can be contained on all sides, within the overflow area 135, such that the TIM 150 is unable to flow past the second barrier 140.

FIGS. 2A-2B show cross-sectional side views of a semiconductor assembly 200 including a double barrier system, at different stages of assembly with a TIM, in accordance with some implementations of the disclosure. FIG. 2A shows the semiconductor assembly 200 with the double barrier system, after directly applying the TIM 250 to a heat generating device or semiconductor chip/die 220. FIG. 2B shows the semiconductor assembly 100 with the double barrier system, during compression with a heat transferring device 260, showing a liquid metal contained by the double barrier system.

Depending on the form of the heat transferring device 260, FIGS. 2A-2B can be representative of the TIM 0 configuration or TIM 1 configuration. Where the heat transferring device 260 represents a heat spreader or package lid, the configuration can be called the TIM 1 configuration. In this configuration, the heat sink can then be mounted to the lid. Where the heat transferring device 260 represents a heat sink mounted directly to the heat generating device 220, the configuration can be called the TIM 0 configuration.

As depicted by FIG. 2A, a die 220, a first barrier 230, and a second barrier 240 are affixed to a substrate 210, prior to compression of the semiconductor assembly 200. The die 220 can be a PCB mounted to substrate 210 using a conductive adhesive. Examples of conductive adhesives include solder, sintering pastes, and metal-filled conductive adhesives. The conductive adhesive (not shown) can be located between the bottom side of the heat generating device 220 and the substrate 210. Exposing the heat generating device 220 to a thermal reflow can securely fasten the heat generating device 220 to the substrate 210.

In this example, a TIM 250 is in touching relation with the heat generating device 220. The TIM 250 can be dispensed, jetted, brushed, or applied to the top side of the heat generating device opposite the side affixed to the substrate 210. The distance from the top of the substrate 210 to the top of the TIM is defined as h3. The first barrier 230 can be attached onto the substrate 210, in touching relation with the four sides of the heat generating device 220, perpendicular to the plane of the heat generating device 220 touching the TIM 250.

The first barrier 230 can be comprised of dielectric material that prevents the barrier from electronically interacting with the TIM 250 or components on the substrate 210. The first barrier 230, post-curing, can be firm but flexible and have a low thermal conductivity to promote the heat flow from the heat generating device 220 toward the heat transferring device 260 rather than through the first barrier 230.

The first barrier 230 can be formed of a gasketing material or resin such as the Dymax® Ga-201 one-part, UV curable, acrylated urethane. Such resin material can provide a soft, tack-free, flexible gasket barrier to prevent moisture, gases, and liquids, including liquid metal, from penetrating the resin. During assembly of semiconductor assembly 200, first barrier 230 can be dispensed through a syringe or nozzle in liquid or gel form and cured in place using ultraviolet light to solidify the first barrier, prior to placement of the heat transferring device 260. In other implementations, the resin can be thermally cured provided that the temperature does not exceed the solidus point of the solder used to affix heat generating device 220 to the substrate 210, which could cause detachment of the heat generating device 220.

In addition to providing a gasketing seal around the heat generating device 220 the first barrier 230 can serve to control the standoff between the heat generating device 220 and the heat transferring device 260.

During assembly of semiconductor assembly 200, after the heat generating device 220 is affixed to the substrate 210 and the first barrier 230 is dispensed onto the substrate surrounding the heat generating device 220, and cured (e.g., using UV light), the second barrier 240 can be dispensed onto the substrate 210 such that it surrounds the first barrier 230. In this example, the second barrier 240 is in touching relation with the substrate 210. The first barrier 230 and the second barrier 240 are not in touching relation such that the overflow area 235 is created between the first barrier 230 and the second barrier 240.

The overflow area 235 between the first barrier 230 and second barrier 240 can have a width ranging from 1 mm to 10 mm depending on the die size and the volume of TIM 250 needed to cover the die 220. As depicted by FIG. 2B, an excess of TIM 250 can be dispensed onto the die 220 such that when the heat transferring device 260 is compressed onto the semiconductor assembly or package 200, the TIM 250 flows to fill any voids on the surface of the die and can flow over the first barrier 230 into the overflow area 235. The second barrier 240 can serve to contain the overflowed TIM 250 within the overflow area 235.

In some implementations, the second barrier 240 is cured in-situ in coordination with compressing the heat transferring device 260 onto the second barrier 240. As depicted by FIG. 2B, the heat transferring device 260 can be compressed until it comes in contact with the TIM 250 and further compressed until the heat transferring device 260 comes in contact with the first barrier 230. The first barrier 230 can serve as a standoff to control the distance between the heat generating device 220 and the heat transferring device 260. As the heat transferring device 260 is lowered onto the second barrier 240 and compressed, the excess of TIM 250 can flow over the first barrier 230 and into the overflow area 235 until the first barrier 230 becomes in touching relation with the heat transferring device 260.

Once the heat transferring device 260 is in touching relation with the first barrier 230, the uncured second barrier 240 will have been compressed and can be cured in-situ such that the second barrier 240 is affixed to and connects the substrate 210 to the heat transferring device 260. The second barrier 240 can be cured thermally or by UV light and may require fixturing during the curing process to maintain the compression.

The attachment illustrated by FIG. 2B can provide a hermetic seal to prevent the leakage of the TIM 250 past the second barrier 240 and to prevent moisture and gasses from entering the package which may degrade the TIM 250. The connection of the second barrier 240 to the substrate 210 can keep the heat transferring device 260 in touching relation with the first barrier 230 to maintain the predetermined distance between the heat generating device 220 and the heat transferring device 260. As shown in FIGS. 2A-2B, this standoff distance can be determined by subtracting the distance h2−h1, where h1 equals the distance from the substrate 210 to the top surface of the die 220, and h2 equals the height of the first barrier 230. In FIG. 2B, post compression, h2−h1 effectively equals the distance from the top of the heat generating device 220 to the bottom of the heat transferring device 260. In between these two devices the TIM 250 can be in touching relation with the die 220, the interior walls of the first barrier 230 extending from the top of the die 220 to the bottom of the heat transferring device 260, and in touching relation with the bottom of the heat transferring device 260 described as the plane mirroring the top of the die 220 projected onto the heat transferring device 260.

The standoff distance h2−h1 can range in height from 10 microns to 3,000 microns depending on the application. A computer processing unit (CPU) chip or tensor processing unit (TPU) chip may require a standoff of 30-150 microns whereas a power electronics chip may require a standoff of 100 microns to 3,000 microns.

As shown in FIGS. 2A-2B, h4 is defined as the height of the second barrier 240. This is the distance from the substrate 210 to the top of the second barrier 240. In some implementations, h4 can range from 10 microns to 3000 microns. During compression of the semiconductor package 200, h4 can be substantially equal to h2 and h3, as shown in FIG. 2B. Prior to compression of the semiconductor package 200, h1<h2<h3<h4 as shown in FIG. 2A.

In addition to containing the excess of TIM 250 within the overflow area 235, the second barrier 240 can provide a hermetic seal such that all TIM is contained within the second barrier 240, as shown in FIG. 2B. The hermetic seal can provide resistance to oxidization of the TIM 250 during temperature and humidity testing and during operation of the device in harsh or normal operating conditions.

The second barrier 240 can be formed of a gasketing material such as the Dow Corning® SE 4450 one-part, thermally curable, silicone. This thermally conductive adhesive has a high tensile strength and is designed to provide thermal transfer for the cooling of die packages such as TIM 0 or TIM 1. The silicone can be dispensed manually or by dispensing equipment onto the substrate 210 to create the second barrier 240.

As discussed above, the heat transferring device 260 can be lowered onto the semiconductor assembly, until it is in touching relation with the uncured second barrier 240. The semiconductor assembly 200 can then be further compressed against the second barrier 240 until the heat transferring device 260 comes in touching relation with both the TIM 250 and the pre-cured first barrier 230. The semiconductor assembly 200 can then be fixtured to hold this compressed position. The second barrier 240 can then be cured in place by ultraviolet light or by thermal means to securely fasten the second barrier 240 to both the substrate 210 and the heat transferring device 260. The fixturing can then be removed.

In some implementations, the first barrier 230 and/or the second barrier 240 can be formed of one or more electrically insulating polymers such as acetal homopolymer, acrylonitrile-butadiene-styrene (ABS) copolymers, fluoropolymers, organic polymers, perfluoroelastomers (FFKM), phenolic resins, poly(butylene terephthalate) (PBT), poly(ethylene terephthalate) (PET), poly(polyphosphonate-co-carbonate) copolymers, poly(polyphosphonate-co-carbonate) reactive oligomers, poly(p-phenylene sulfide), polyamides (nylons), polyesters, polyimides, polytetrafluoroethylene (PTFE), silicates, boron nitrogen polymers, thermoplastic polyester elastomers, and the like. In some implementations, the first barrier 230 and/or the second barrier 240 can include one or more of the following: epoxy, acrylate, epoxy acrylate, urethane, urethane acrylate, cyanoacrylate, silicone, or fluorinated or non-fluorinated poly(p-xylylene) (Parylene).

As discussed above, semiconductor packages assembled using the double barrier system described herein can provide multiple advantages not found in some prior semiconductor assemblies. The second barrier can hermetically seal the package. Additionally, once the heat transferring device is in contact with the first barrier 230, a predetermined standoff height can be created between the heat generating device 220 and the heat transferring device 260. Furthermore, during compression, the excess of TIM 250 can spread over the entire top surface of the heat generating device 220 to remove any voids or bare spots. Excess TIM can flow from the top of the heat generating device 220 into the overflow area 235 where it can be securely contained. Once the second barrier is cured, a voidless pool of TIM can be contained within the cavity created by the four sides of the first barrier 230, the top of the heat generating device 220, and the bottom the of the heat transferring device 260, optimizing thermal performance of the semiconductor device 200.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

It should be appreciated that all combinations of the foregoing concepts (provided such concepts are not mutually inconsistent) are contemplated as being part of the inventive subject matter disclosed herein. In particular, all combinations of claimed subject matter appearing in this disclosure are contemplated as being part of the inventive subject matter disclosed herein.

What is claimed is:

1. An assembly, comprising:
a substrate;
a heat generating device including a first surface attached to the substrate;
a first barrier surrounding and in touching relation with the heat generating device;
a second barrier surrounding the first barrier such that there is an area between the first barrier and the second barrier;
a heat transferring device; and
a thermal interface material between and in touching relation with the heat transferring device and a second surface of the heat generating device opposite the first surface.

2. The assembly of claim 1, wherein the heat transferring device is in touching relation with the first barrier and the second barrier.

3. The assembly of claim 2, wherein the first barrier and the second barrier are in touching relation with the substrate.

4. The assembly of claim 3 wherein:
a height of the first barrier is substantially equal to a height of the second barrier; and
the height of the first barrier is substantially equal to a distance between a surface of the heat generating device contacting the substrate and a surface of the heat transferring device contacting the thermal interface material.

5. The assembly of claim 1, wherein the thermal interface material fills at least part of the area between the first barrier and the second barrier.

6. The assembly of claim 5, wherein the thermal interface material is hermetically sealed by the second barrier.

7. The assembly of claim 5, wherein the area continuously surrounds a perimeter of the first barrier such that the first barrier and the second barrier are not in touching relation anywhere.

8. The assembly of claim 1, wherein the first barrier and the second barrier comprise a dielectric material.

9. The assembly of claim 8, wherein the dielectric material comprises silicone or a urethane acrylate.

10. The assembly of claim 1, wherein the thermal interface material comprises gallium, indium, tin, copper, zinc, gold, silver, antimony, or bismuth.

11. The assembly of claim 10, wherein the thermal interface material comprises gallium and indium in a ratio ranging from 3:1 to 4:1 of gallium to indium.

12. The assembly of claim 10, wherein the thermal interface material comprises:
61 wt % to 68.5 wt % gallium;
20 wt % to 25 wt % indium;
8 wt % to 16 wt % tin; and
optionally, greater than 0 wt % to 2 wt % zinc.

13. The assembly of claim 1, wherein:
the heat generating device comprises a semiconductor die; and
the heat transferring device comprises a heat sink or heat spreader.

14. A method, comprising:
attaching a first surface of a heat generating device to a substrate;
placing, on the substrate, a first barrier that surrounds and is in touching relation with the heat generating device;
placing, on the substrate, a second barrier that surrounds the first barrier such that there is an area between the first barrier and the second barrier;
after placing the first barrier and the second barrier, applying a thermal interface material on a second surface of the heat generating device opposite the first surface; and
compressing a heat transferring device over the heat generating device until a surface of the heat transferring device is in touching relation with the thermal interface material applied on the second surface of the heat generating device.

15. The method of claim 14, further comprising: prior to compressing the heat transferring device over the heat generating device, curing, using heat or ultraviolet light, the first barrier to a solid form, wherein during compression of the heat transferring device over heat generating device, the first barrier in the solid form controls a standoff height between the heat generating device and the heat transferring device.

16. The method of claim 14, wherein compressing the heat transferring device over the heat generating device comprises compressing the heat transferring device until the surface of the heat transferring device is in touching relation with the first barrier, the second barrier, and the thermal interface material.

17. The method of claim 14, wherein compressing the heat transferring device over the heat generating device comprises compressing the heat transferring device such that a portion of the thermal interface material flows over the first barrier into the area between the first barrier and the second barrier.

18. The method of claim 16, wherein:
compressing the heat transferring device over the heat generating device comprises compressing the second barrier to a compressed state; and
the method further comprises: after compressing the heat transferring device over the heat generating device, curing the second barrier in the compressed state.

19. The method of claim 16, wherein prior to compressing the heat transferring device over the heat generating device:
a height of the first barrier is less than a height of the second barrier; and
a height of the first barrier is less than a combined height of the heat generating device and the thermal interface material on the second surface of the heat generating device.

20. The method of claim 19, wherein after compressing the heat transferring device over the heat generating device:
the height of the first barrier is substantially the same as the height of the second barrier, and
the height of the first barrier is substantially the same as the combined height of the heat generating device and the thermal interface material on the second surface of the heat generating device.

21. The method of claim 14, wherein:
the heat generating device comprises a semiconductor die; and
the heat transferring device comprises a heat sink or heat spreader.
